(19) United States
(12) Patent Application Publication
(10) Pub. No.: US 2010/0228515 A1
(43) Pub. Date: Sep. 9, 2010

(54) MULTI-FRAME TEST SIGNALS MODULATED BY DIGITAL SIGNAL COMPRISING SOURCE FOR TESTING ANALOG INTEGRATED CIRCUITS

(75) Inventors: GANESH P. SRINIVASAN, DALLAS, TX (US); FRIEDRICH J. TAENZLER, PLANO, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INC, DALLAS, TX (US)

(21) Appl. No.: 12/399,687

(22) Filed: Mar. 6, 2009

(51) Int. Cl. G01R 31/00; G06F 19/00

(52) U.S. Cl. 702/124; 324/537

(57) ABSTRACT

A method of generating multi-frame test signals, a testing apparatus, and method for testing integrated circuits (ICs) with the multi-frame test signals. An analog source generates an analog source signal at a constant power and a constant frequency that is modulated with a first modulating signal (e.g., I) to output a first test signal having first signal parameters including a power level, a frequency and a modulation scheme. The modulating is repeated with a second modulating signal (e.g., Q) to output a second test signal having second signal parameters including a power level, a frequency and a modulation scheme. At least one of the first and second signal parameters are different. The modulating signals are generated by a digital signal source. The first and second test signal are combined by placing the first test signal on the first frame (frame 1) and the second test signal on the second frame (frame 2) of the multi-frame test signal.

### FIELD OF THE INVENTION

Embodiments of the present invention relate to testing of analog integrated circuits (ICs).

### BACKGROUND

Improvements in high-frequency electronic devices for consumer products such as cellular telephones, pagers, and wireless personal data assistants (PDAs) have given rise to a need for improved electronic testing. A testing apparatus for testing a device under test (DUT) performs the test by having one testing module generate and supply a test signal to the DUT and another testing module measure the output signal from the DUT.

The accuracy of analog such as radio frequency (RF) test equipment limits the ability to accurately measure certain device parameters. Such accuracy limitations affect both production and characterization activities. For example, tests for “modulation error” or “gain step accuracy” parameters each require multiple measurements to be performed to allow calculation of the parameter.

Modulation error for communication devices can be defined as the delta (change) in transfer function between modulated and un-modulated (CW) measurements under the same external test conditions. In such tests it become necessary to have a high degree of repeatability in the test signal source, such as relative level uncertainty between modulated and un-modulated (CW) test signals of the same RMS power level within 0.1 dB or better of the target value.

A gain step test can be broadly defined as any test used to guarantee the transfer function of the DUT over a certain power, frequency, temperature or other parameter.

The actual measurement technique used to guarantee this specification depends on the final application of the DUT. For example, for an analog/RF filter this specification may be a transfer function over a range of frequency, and for an analog/RF power amplifier this may be a P1 dB or a P0.1 dB type test. In another example, for an RF RMS power detector device, this specification may be RF power to output DC voltage transfer function. Some of the current generation RF devices require an absolute power level accuracy (level uncertainty) of 0.1 dBm or better at each power or frequency iteration during the gain step accuracy test.

However, analog/RF sources (e.g. local oscillators (LOs)) provided by conventional production testers include level uncertainty specifications in their analog/RF test signal sources that are generally at least five (5) times that of the device specification. Moreover, the level uncertainty of the test signal can increase (worsen) further with frequency, temperature, calibration and automation level control settings. Such level uncertainties make it generally impossible to guarantee specification compliance for certain parameters for a variety of devices.

### SUMMARY

This Summary is provided to comply with 37 C.F.R. §1.73, presenting a summary of the invention to briefly indicate the nature and substance of the invention. It is submitted with the understanding that it will not be used to interpret or limit the scope or meaning of the claims.

As described above, analog/RF sources provided by conventional production testers include level uncertainty specifications in their analog/RF test signal sources that are generally at least five (5) times and generally ten (10) times that of the specification for the device. Such level uncertainties makes it generally impossible to guarantee specification compliance for certain parameters, such as gain step accuracy and modulation error. Embodiments of the invention generally solve this problem by providing multi-frame test signals derived from digital signal comprising sources that have been found to generate test signals that are significantly more accurate, such as approximately a 10× accuracy improvement.

As used herein, multi-frame test stimulus signals are defined as a collection of multiple (at least two) individual test signals, each test signal occupying a certain time period (e.g. time frame) with at least one varying parameter between the respective signals, such as, but not limited to frequency, power or modulation scheme. For example, during one frame the signal can be constant with respect to a defined power level, frequency and modulation scheme, and a change of one of these settings is considered as constituting new frame.

For example, as described in the Examples below, a test signal source according to an embodiment of the invention can provide a level uncertainty of 0.05 dB or better in the relative sense. Such multi-frame test signals generally enable measurement of test parameters such as gain step accuracy and modulation error in a specification compliant manner. More generally, embodiments of the invention can significantly benefit a variety of devices that need accurate parameter measurement for one or more parameters that are calculated from relative measurements.

Embodiments of the present invention describe methods of generating multi-frame test signals for testing integrated circuits (ICs), and IC testers and testing of ICs using such multi-frame test signals. Embodiments of the invention generally transfer the primary accuracy limiter in the test signal generation module from the RF source (e.g. local oscillator) to a digital to analog converter (DAC). A waveform memory provides an essentially infinite number of waveforms which are each defined by a plurality of digital sample points, which upon analog conversion reconstructs the corresponding analog waveforms (e.g. sine waves), referred to herein as modulating signals based on their use as described below.

To form the multi-frame test signals, an analog source, such as a conventional LO is provided for generating an analog source signal that is maintained at a constant power and a constant frequency. The analog source signal is modulated with a first modulating signal to output a first test signal having first signal parameters comprising a first power level, a first frequency and a first modulation scheme. The modulating is repeated (e.g. at a later time) with a second modulating signal to output a second test signal having second signal parameters comprising a second power level, a second frequency and a second modulation scheme. At least one of the second signal parameters are different as compared to the first signal parameters. As used herein, the modulating signals are defined to include both un-modulated (CW; e.g. DC) and modulated signals (e.g. sine waves).

As described above, the first modulating signal and the second modulating signal are both generated by a digital signal comprising source comprising a waveform memory. The first test signal and the second test signal are then combined by positioning them on a first and a second frame of a multi-frame test signal comprising a plurality of frames, wherein the first test signal is positioned in the first frame and the second test signal is positioned in the second frame. The plurality of frames of the multi-frame test signal generally comprises of a collection of cw frames, a collection of modulated frames or a collection of cw and modulated frames.

The plurality of frames of the multi-frame test signal generally comprises at least one CW frame and at least one modulated frame, such as a plurality of CW frames and a plurality of modulated frames.

Using triggering for synchronization, ICs can be tested using multi-frame signals according to embodiments of the invention on a frame-by-frame basis. As a result, a significant speed up in test time results as compared to conventional test techniques which require multiple test setups to obtain the test data provided by a single multi-frame test signal according to an embodiment of the invention. Embodiments of the invention also provide the opportunity for averaging by using a plurality of source and capture samples within in each frame.

### BRIEF DESCRIPTION OF THE DRAWINGS

FIG. 1 is a flow chart for a method of generating multi-frame test signals for testing ICs, according to an embodiment of the invention.

FIG. 2A shows a simplified depiction of a multi-frame test signal that includes a plurality of frames, according to an embodiment of the invention.

FIG. 2B shows a depiction for an exemplary multi-frame test signal including exemplary waveforms in the specific case the modulation signals are in the In-phase and Quadrature (IQ) format, according to an embodiment of the invention.

FIG. 3 shows a simplified diagram of architecture for test signal generating system including circuitry and related components for generation of multi-frame test signals in the IQ format, according to an embodiment of the invention.

FIG. 4 is a block diagram of an exemplary testing apparatus for performing testing of an analog device under test (DUT) including a testing module to generate and supply a test signal to the DUT and another testing module to measure the output signal from the DUT, according to an embodiment of the invention. Exemplary waveforms are also provided.

FIG. 5 shows actual test data comprising a validation plot for the relative errors obtained using an embodiment of the invention on a production RF ATE while testing a RMS detector device.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

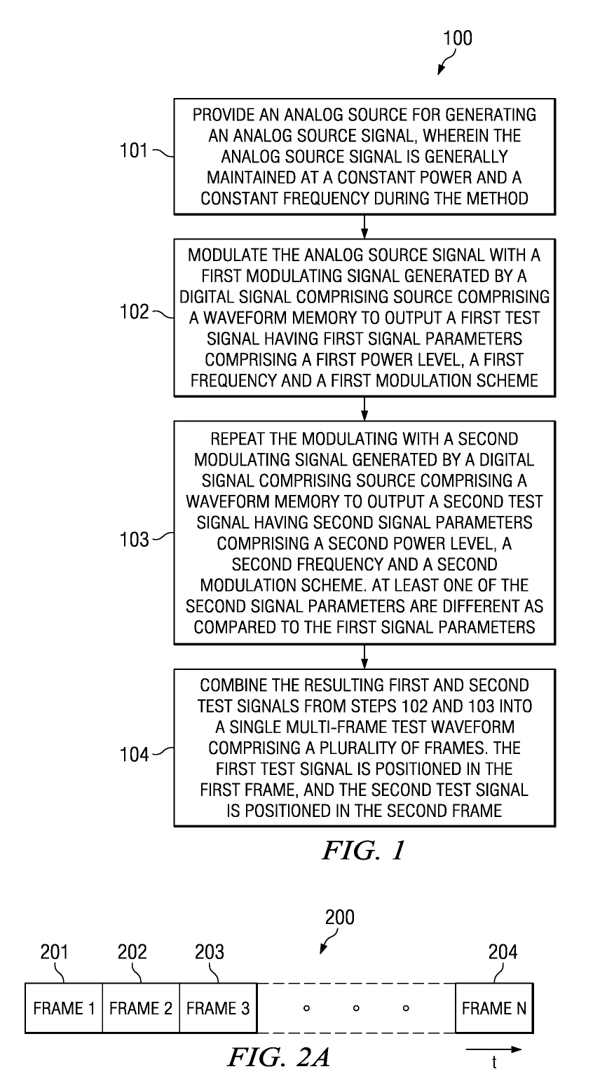

Embodiments of the invention provide multi-frame test signals for testing ICs that provide improved accuracy, including higher level accuracy, as compared to conventional analog test signals. Referring to FIG. 1, in one embodiment of the invention, a method 100 of generating multi-frame test signals for testing ICs is provided. Method 100 includes step 101 that comprises providing an analog source, such as a conventional LO, for generating an analog source signal. The analog source signal is generally maintained at a constant power and a constant frequency during method 100. The frequency range for the analog source is generally in a range from 1 kHz to 10 GHz. The modulation mode for the analog source is turned on. If available, the automatic level control (ALC) operation for the analog source is turned off. As used herein, constant power refers to the resulting amplitude of the analog source signal with the level control turned off or disabled.

Steps 102 and 103, described below, each comprise generating CW or modulated test signals of varying power, frequency, modulation scheme or other parameter or characteristic through modulating the analog source signal using a series of modulating signals. The series of modulating signals can be in the form of swept signals, such as modulating signals having monotonically increasing power (e.g., 1 db steps). In step 102 the analog source signal is modulated with a first modulating signal to output a first test signal having first signal parameters comprising a first power level, a first frequency and a first modulation scheme. A conventional modulator (e.g., balanced modulator) may be used for the modulating. Step 103 comprises repeating the modulating (e.g., at a later time, or with redundant circuitry, potentially at the same time) with a second modulating signal to output a second test signal having second signal parameters comprising a second power level, a second frequency and a second modulation scheme. At least one of the second signal parameters are different as compared to the first signal parameters.

The first modulating signal and the second modulating signal are both generated by a digital signal comprising source comprising a waveform memory. The digital signal comprising source can comprise, for example, an arbitrary waveform generators (AWG), arbitrary function generator (AFG), or data or pattern generator (DG).

In step 104, the resulting first and second test signals from the sweeps or other non-constant parameter pattern generated from steps 102, 103, etc. are then combined (e.g., pasted) into a single multi-frame test waveform comprising a plurality of frames (each frame having a different time segments) each representing potentially different test signal settings. The first test signal is positioned in the first frame, the second test signal is positioned in the second frame, etc. The multi-frame test signal generally includes at least one CW and/or at least one modulated frame, and generally comprises a plurality of each frame type.

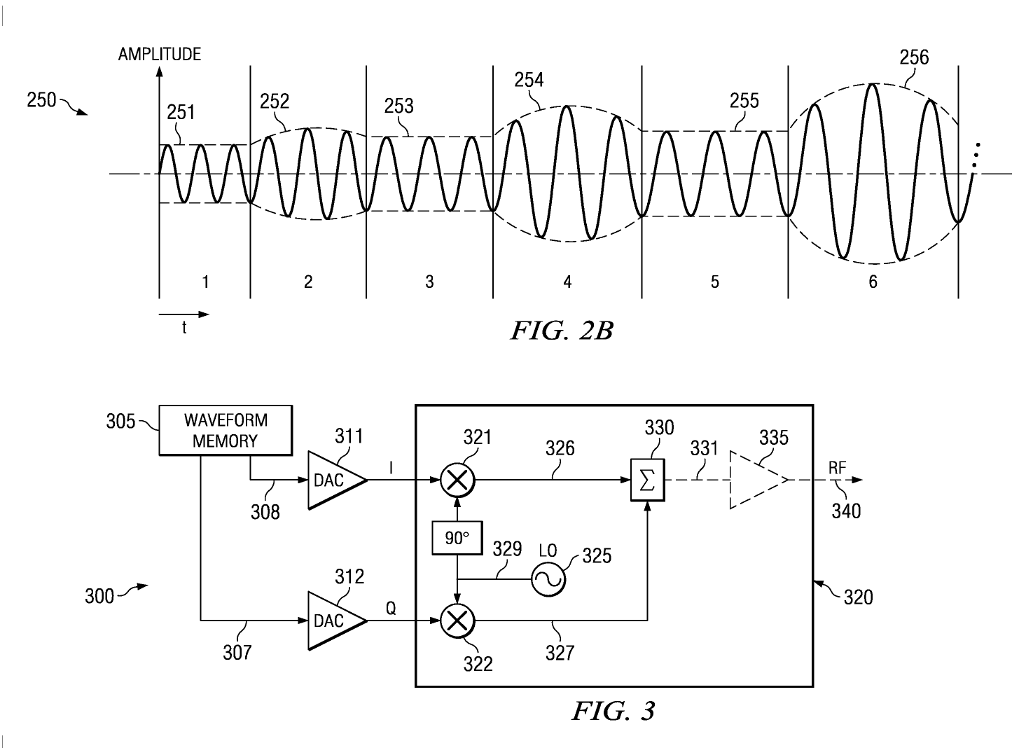

FIG. 2A shows a simplified depiction 200 of an exemplary multi-frame test signal that includes a plurality of frames, frame 1, 2, 3 and N, shown as 201, 202, 203 and 204, respectively, according to an embodiment of the invention. For example, frames 201 and 203 can be CW frames, and frames 202 and 204 modulated frames. The parameters for the respective frames of the multi-frame test signal can be based on the particular test requirement.

FIG. 2B shows a depiction for an exemplary multi-frame test signal 250 including exemplary waveforms according to an embodiment of the invention in the specific case the modulation signals are in the IQ format. The IQ signal of the required peak-to-peak value is used to modulate the analog source signal. Frames 1-6 are identified by reference numbers 251-256.

Frames 251, 253 and 255 are CW frames and frames 252, 254, and 256 are modulated frames that result when the analog source signal is modulated with an appropriate modulated signal. For CW signal generation, the analog source signal can be set to a constant amplitude and frequency in the modulated mode. An appropriate signal such as a DC signal with the required voltage value is used to modulate the analog source. The amplitude of the DC signal can control the analog (e.g., RF) signal strength for power steps in the amplitude sweep.

For modulated signal generation, the desired modulation such as AM, FM, FSK, GMSK can be created using a signal processing tool such as MATLAB™ in the IQ format. This IQ signal of the required peak-to-peak value can be used to modulate the analog source. As known in the art, the IQ signals are generally centered at 0 Hz to avoid image signal issues.

The peak-to-peak amplitude levels of frames 251=252 (both @ level=v1)<253=254 (both @level=v2)<255=256 (both @level=v3). Multi-frame test signal 250 can be useful for modulation error testing, where respective DUT outputs responsive to frames 251 and 252 can be used to calculate the modulation error at v1, DUT outputs responsive to frames 253 and 254 can be used to calculate the modulation error at v2, and DUT outputs responsive to frames 255 and 256 can be used to calculate the modulation error at v3, etc., all from the same multi-frame test signal 250.

FIG. 3 shows a simplified diagram of architecture for test signal generating system 300 including circuitry and related components for generation of multi-frame test signals in the IQ format, according to an embodiment of the invention. System 300 comprises a waveform memory 305. Waveform memory 305 stores binary words. For example, AWGs generally include a set of basic functions stored permanently within the instrument for recall into the waveform memory 305. Waveforms created with external languages such as MATLAB™ can be ported into the waveform memory 305. Waveform memory is shown outputting two (2) signals, 307 and 308, which are coupled to DACs 311 and 312, respectively. The output of DAC 311 is shown as being the I signal, and the output of DAC 312 as the Q signal. The I and Q signals are coupled into modulator/combiner block 320. Modulator/combiner block 320 comprises modulators 321 and 322, such as balanced modulators. Modulators 321 and 322 modulate the analog source signal provided by the analog source 325, shown as a LO, which provides the analog source signal 329. The output from modulator 321 shown as 326, is combined with the output from modulator 322, shown as 327 at combiner 330 which algebraically sums outputs 326 and 327 to provide a single signal 331 containing both the I and Q information. The output of combiner 330 is coupled to amplifier 335. The output from amplifier 335 is shown as RF output 340, which more generally provides the multi-frame test signal, such as multi-frame test signal 250 shown in FIG. 2B.

In operation of system 300, the analog source signal 329 provided by the LO 325 is maintained at a constant power (i.e., amplitude) and a constant frequency. Outputs from the waveform memory 307 and 308 can be changed (e.g., via test program software) to initiate new frames to provide modulating signals having at least one changed parameter. Because the stored signal information in waveform memory 305 comprises digital samples, the outputs provided by waveform memory 307 and 308 can be modified in many different ways, such as filtered, amplified, convolved, time-shifted, modulated, and more. The output frequency can be changed, without altering the waveform content, simply by changing the frequency of the sample clock (not shown).

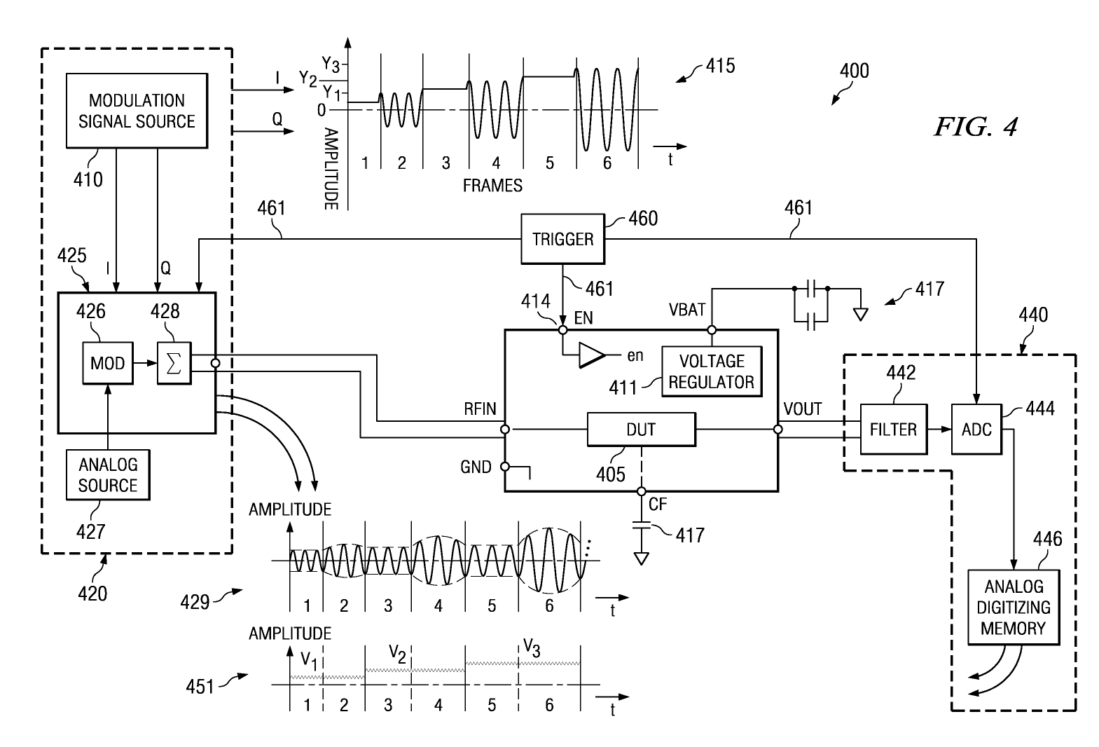

FIG. 4 is a block diagram of an exemplary test apparatus 400 for testing an analog device under test (DUT) 405. Apparatus 400 includes a first testing module 420 for generating and supplying multi-frame test signals to the DUT 405 and a second testing module 440 for measuring the output signal from the DUT 405, according to an embodiment of the invention. First testing module 420 comprises modulation signal source 410 which in one embodiment corresponds to waveform memory 305 and DACs 311 and 312 shown in FIG. 3. Exemplary waveforms output by modulation signal source 410 are shown as reference 415 for frames 1-6. Odd numbered frames 1, 3, 5 are shown as CW signals, while even number frames 2, 4 and 6 are shown as modulated signals. Amplitudes are shown on the y-axis, while time is the x-axis parameter.

First testing module 420 also includes modulator/combiner block 425 which is coupled to receive the I and Q signals from modulation signal source 410. Modulator/combiner block 425 comprises at least one modulator 426, and a combiner 428. First testing module 420 also includes analog source 427, which can be an RF source (e.g., LO). In one embodiment, modulator/combiner block 425 together with analog source 427 corresponds to component arrangement of modulator/combiner block 320 shown in FIG. 3. The output from modulator/combiner block 425 corresponding to frames 1-6 is shown as waveforms 429.

Second testing module 440 is for measuring output signals from the output of the DUT 405. As shown in FIG. 4, second testing module 440 comprises in serial connection filter 442, analog to digital converter (ADC) 444, and analog digitizing memory 446. The output of analog digitizing memory 446 corresponding to frames 1-6 is shown as waveforms 451 shown in FIG. 4.

A power supply comprising a voltage regulator 411 that provides a regulated supply voltage VBAT is shown coupled to the DUT 405, the enable node 414 shown when enabled by the enable signal “en” allows testing of the DUT 405. Decoupling capacitors 417 are for shunting high frequency power supply noise are also shown.

A trigger block 460 is shown in FIG. 4. The triggering signal 461 provided by triggering block 460 is coupled to modulator/combiner block 425, the enable node 414 associated with DUT 405, and ADC 444. The triggering signal 461 allows the output signal from the DUT 405 responsive to the multi-frame test signal to be captured in the time domain and each frame analyzed individually. Based on the analyzed results, test parameters such as gain step accuracy and modulation error specifications can then be calculated.

In the case the DUT 405 comprises an RF power sensor device, gain step accuracy and modulation error specification testing can comprise exemplary test signal requirements include a power sweep CW signal @800 MHz from −25 dBm to +3 dBm at 1 dB steps and measuring the corresponding sensor outputs. Averaging a plurality of measurements within a frame can be used obtain generally more stable and repeatable measurements. The power sweep is repeated at @2,000 MHz. The power sweep is then repeated at both frequencies (800 MHz and 2,000 MHz) for the modulated signal.

Since data capture is in the time domain, multiple samples of the same measurement can be captured in each frame to perform averaging. This helps in reducing the overhead test time for averaging with individual measurements. The data can be analyzed in the ATE DSP, or as a background process while the ATE is executing another test.

As described above, methods according to the invention transfer the accuracy specification from the RF source to the DAC associated with the digital signal comprising source (e.g., AWG), which has been found to be typically about 10× more accurate. As described below in the Examples, such an approach results in a test signal source with a level uncertainty of 0.05 dB or better in both the relative and absolute sense. Moreover, a significant test time speed up can also be obtained as a single multi-frame signal that is typically a low-frequency signal, each having different Vpp levels (if needed) can be sourced and the corresponding output signal of the DUT can be captured using triggering for synchronization and processed to calculate the specification of interest. Embodiments of the invention also eliminate the need for multiple test setups and also provides an opportunity for averaging by increasing the number of source and capture samples in each frame. Embodiments of the invention are believed to be the first method disclosed to measure the gain step accuracy and modulation error in a specification compliant manner for RMS detectors and related devices.

Embodiments of the invention can be extended to P1 dB or P0.1 dB tests by replacing the traditional P1 dB or P0.1 dB test procedure wherein the source power is re-programmed at each step. As described above, embodiments of the invention can be used to pack multiple power steps in a single modulated multi-frame signal. Such a multi-frame signal can be used to drive the DUT and from the captured response over time, and the output power, the gain values for the individual power levels can all be calculated at a single shot. These individual gain values can be processed in the same way as it is commonly done with the interpolation method.

### EXAMPLES

Embodiments of the present invention are further illustrated by the following specific Examples, which should not be construed as limiting the scope or content of embodiments of the invention in any way.

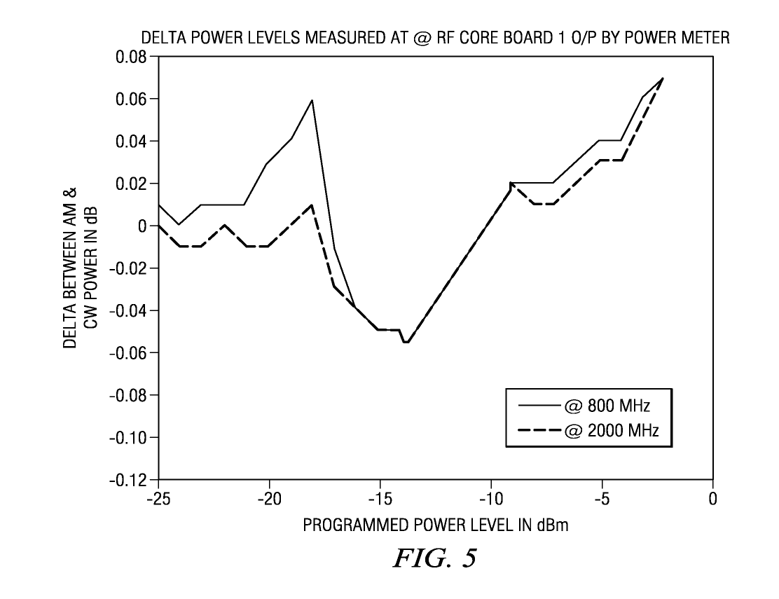

FIG. 5 shows actual test data comprising a validation plot for the relative errors obtained using an embodiment of the invention on a production RF ATE while testing an RMS detector. The X-axis is the programmed RF power level in dBm. Along the Y-axis is the delta between AM and CW measured power in dB between successive power steps measured using a Agilent Power Meter at (a) 800 MHz and (b) 2000 MHz. Data at −10 dBm is removed due to error at ˜−10 dBm due to an error on the Power Meter as it switches attenuations steps at this power level. Since the delta between AM and CW measured power in dB between successive power steps for the RMS detector is shown in FIG. 5 to generally be <0.05 dB, the test signal source necessarily must have provided a level uncertainty of 0.05 dB or better. Thus, the RMS power detector can be tested for its RF power to output DC voltage transfer function with an absolute power level accuracy (level uncertainty) of 0.1 dBm or better at each power or frequency iteration during the gain step accuracy test.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

We claim:

1. A method of generating multi-frame test signals for testing integrated circuits (ICs), comprising:
providing an analog source for generating an analog source signal, said analog source signal maintained at a constant power and a constant frequency;
modulating said analog source signal with a first modulating signal to output a first test signal having first signal parameters comprising a first power level, a first frequency and a first modulation scheme; and
repeating said modulating with a second modulating signal to output a second test signal having second signal parameters comprising a second power level, a second frequency and a second modulation scheme, at least one of said second signal parameters being different as compared to said first signal parameters;
wherein said first modulating signal and said second modulating signal are both generated by a digital signal comprising source comprising a waveform memory, and
combining said first test signal and said second test signal on a first and a second frame of a multi-frame test signal comprising a plurality of frames, wherein said first test signal is positioned in said first frame and said second test signal is positioned in said second frame.

2. The method of claim 1, wherein a power level of said first test signal and said second test signal are different, said power levels being controlled by said first and second modulating signals.

3. The method of claim 1, wherein said multi-frame test signal comprises a power sweeping signal monotonically increasing with successive ones of said plurality of frames.

4. The method of claim 3, wherein pairs of adjacent frames of said plurality of frames comprise a CW frame and a modulated frame that both have a common power level.

5. The method of claim 1, wherein said digital signal comprising source comprises an arbitrary waveform generators (AWG), arbitrary function generator (AFG) or data or pattern generator (DG).

6. The method of claim 1, wherein said plurality of frames comprise at least one CW frame and at least one modulated frame.

7. The method of claim 6, wherein said first modulating signal comprises a DC signal having a voltage amplitude for controlling a power level of said CW frame, and said second modulating signal comprises an IQ signal comprising an I and a Q signal, wherein a peak-to-peak voltage amplitude of said IQ signal controls a power level of said modulated frame.

8. The method of claim 6, wherein said first modulating signal comprises a complex modulation signal for controlling a power level of said CW frame, and said second modulating signal comprises an IQ signal comprising an I and a Q signal, wherein a peak-to-peak voltage amplitude of said IQ signal controls a power level of said modulated frame.

9. A method of testing an analog integrated circuit (IC), comprising:
coupling a multi-frame test signal to said analog IC, said multi-frame test signal comprising:
a plurality of frames, wherein a first test signal having first parameters comprising a first power level, a first frequency and a first modulation scheme and a second test signal having second parameters comprising a second power level, a second frequency and a second modulation scheme are provided on a first and a second frame of said plurality of frames, respectively, and wherein at least one of said second parameters are different as compared to said first parameters, and
measuring a first output signal responsive to said first test signal and a second output signal responsive to said second test signal from said analog IC, and
calculating at least one parameter for said analog IC using said first and said second output signals.

10. The method of claim 9, further comprising triggering said coupling and said measuring for synchronization.

11. The method of claim 9, wherein said first and said second power level are different, said first and said second power levels being controlled by a first and a second modulating signal, respectively.

12. The method of claim 9, wherein multi-frame test signal comprises a power sweeping signal monotonically increasing with successive ones of said plurality of frames.

13. The method of claim 9, wherein pairs of adjacent frames of said plurality of frames comprise a CW frame and a modulated frame that both have a common power level.

14. The method of claim 9, wherein said multi-frame test signal is generated by a digital signal comprising source that comprises an arbitrary waveform generators (AWG), arbitrary function generator (AFG), or data or pattern generator (DG).

15. The method of claim 9, wherein said plurality of frames comprise at least one CW frame and at least one modulated frame.

16. The method of claim 15, wherein said multi-frame test signal is generated by:
providing an analog source for generating an analog source signal, said analog source signal maintained at a constant power and a constant frequency;
modulating said analog source signal with a first modulating signal to output said first test; and
repeating said modulating with a second modulating signal to output said second test signal;
wherein said first modulating signal and said second modulating signal are both generated by a digital signal comprising source comprising a waveform memory, and
combining said first test signal and said second test signal on said first and said second frame of said multi-frame test signal.

17. The method of claim 16, wherein said first modulating signal comprises a DC signal having a voltage amplitude for controlling a power level of said CW frame, and said second modulating signal comprises an IQ signal comprising an I and a Q signal, wherein a peak-to-peak voltage amplitude of said IQ signal controls a power level of said modulated frame.

18. The method of claim 16, wherein said first modulating signal comprises a complex modulation signal for controlling a power level of said CW frame, and said second modulating signal comprises an IQ signal comprising an I and a Q signal, wherein a peak-to-peak voltage amplitude of said IQ signal controls a power level of said modulated frame.

19. The method of claim 9, wherein said measuring comprises obtaining a plurality of measurements in at least one of said plurality of frames, said calculating comprising averaging said plurality of measurements to calculate said parameter.

20. A testing apparatus for testing an analog integrated circuit (IC), comprising:
a first testing module for generating and supplying multi-frame test signals to said analog IC;
a second testing module for measuring output signals from said analog IC, wherein coupling a multi-frame test signal to said analog IC,
wherein said multi-frame test signal comprises a plurality of frames, including a first test signal having first parameters comprising a first power level, a first frequency and a first modulation scheme and a second test signal having second parameters comprising a second power level, a second frequency and a second modulation scheme are provided on a first and a second frame of said plurality of frames, respectively, wherein at least one of said second parameters are different as compared to said first parameters.

21. The apparatus of claim 20, wherein said multi-frame test signal is generated by:
an analog source for generating an analog source signal, said analog source signal maintained at a constant power and a constant frequency;
a modulator for modulating said analog source signal with a first modulating signal to output said first test signal, and modulating said analog source signal with a second modulating signal to output said second test signal,
further comprising a digital signal comprising source comprising a waveform memory for generating said first modulating signal and said second modulating signal are both generated by a digital signal comprising source, and
a combiner for combining said first test signal and said second test signal on said first and said second frame of said multi-frame test signal.

22. The apparatus of claim 21, wherein said digital signal comprising source comprises an arbitrary waveform generators (AWG), arbitrary function generator (AFG), or a data pattern generator (DG).

23. The apparatus of claim 21, wherein said plurality of frames comprise at least one CW frame and at least one modulated frame.

24. The apparatus of claim 23, wherein said first modulating signal comprises a DC signal having a voltage amplitude for controlling a power level of said CW frame, and said second modulating signal comprises an IQ signal comprising an I and a Q signal, wherein a peak-to-peak voltage amplitude of said IQ signal controls a power level of said modulated frame.

25. The apparatus of claim 23, wherein said first modulating signal comprises a complex modulation signal for controlling a power level of said CW frame, and said second modulating signal comprises an IQ signal comprising an I and a Q signal, wherein a peak-to-peak voltage amplitude of said IQ signal controls a power level of said modulated frame.

26. The apparatus of claim 21, further comprising triggering circuitry for generating a triggering signal, said triggering signal coupled to said first testing module and said second testing module.
